(19) United States
(12) Patent Application Publication
(10) Pub. No.: US 2007/0145607 A1
(43) Pub. Date: Jun. 28, 2007

(54) System to wirebond power signals to flip-chip core

(76) Inventor: Ranjan J. Mathew, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 11/320,282

(22) Filed: Dec. 28, 2005

(51) Int. Cl. H01L 23/52

(52) U.S. Cl. 257/784

(57) ABSTRACT

A system may include an integrated circuit die defining a plurality of inner apertures, and a conductive element disposed on two or more of the plurality of inner apertures and electrically connected to an electrical conductor through the two or more inner apertures. In some embodiments, the integrated circuit die defines a plurality of peripheral apertures and also includes a conductive pillar disposed on one of the plurality of peripheral apertures and electrically connected to a second electrical conductor through the peripheral aperture.

### BACKGROUND

Wirebond packages and flip-chip packages are commonly used to package one or more integrated circuit (IC) die. According to both types of packages, a lower surface of an IC die is coupled to an upper surface of an IC package substrate. A wirebond package includes wires to connect electrical contacts of a rear surface of the IC die to electrical contacts of the IC package substrate. In contrast, a flip-chip package includes electrical interconnects (e.g., solder bumps) to connect electrical contacts of a front surface of an inverted IC die to electrical contacts of the IC package substrate.

A wirebond package is typically less expensive than an equivalent flip-chip package. However, a wirebond package may not be suitable for some applications. An IC die used in a wirebond package requires a peripheral I/O ring that includes the above-mentioned electrical contacts. Accordingly, such an IC die will be larger than would be required if the IC die were intended for a flip-chip package. A wirebond package also delivers power to the periphery of an IC die. Such power delivery is less uniform than the power delivery of a flip-chip package, in which power is delivered more directly to a core of the IC die.

In may be desirable to selectively package an IC die in a wirebond package or a flip-chip package. Due at least to the above-described differences in power delivery and I/O routing, the design and fabrication of an IC die differs substantially depending on whether the IC die will be packaged in a wirebond package or a flip-chip package.

### BRIEF DESCRIPTION OF THE DRAWINGS

FIG. 1 is a top view of an apparatus according to some embodiments.

FIG. 2 is a cross-sectional side view of an apparatus according to some embodiments.

FIG. 3 is a close-up cross-sectional side view of a conductive pillar of an apparatus according to some embodiments.

FIG. 4 is a close-up cross-sectional side view of a conductive element of an apparatus according to some embodiments.

FIG. 5 is a diagram of a process to fabricate an apparatus according to some embodiments.

FIG. 6 is a top view of an IC die,according to some embodiments.

FIG. 7 is a top view of an IC die and a micropassivation layer according to some embodiments.

FIGS. 8A through 8C are cross-sectional side views of an apparatus to illustrate wirebonding according to some embodiments.

FIG. 9 is a cross-sectional side view of an apparatus to illustrate wirebonding according to some embodiments.

FIG. 10 is a cross-sectional side view of an apparatus to illustrate wirebonding according to some embodiments.

FIG. 11 is a side view of an apparatus according to some embodiments.

FIG. 12 is a top view of an IC die including conductive elements, conductive pillars and bonded wires according to some embodiments.

FIG. 13 is a top view of an IC die including conductive elements, conductive pillars and bonded wires according to some embodiments.

FIG. 14 is a top view of an IC die including conductive elements, conductive pillars and bonded wires according to some embodiments.

FIG. 15 is a diagram of a system according to some embodiments.

### DETAILED DESCRIPTION

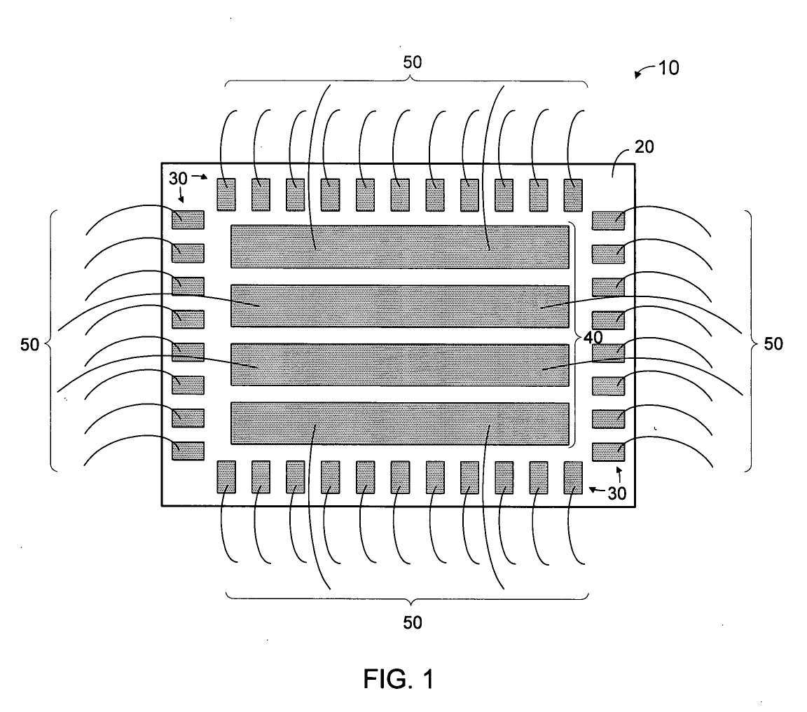

FIG. 1 is a cross-sectional side view of apparatus 10 according to some embodiments. Apparatus 10 includes IC die 20, conductive pillars 30 and conductive elements 40 disposed thereon, and wires 50 bonded to one conductive pillars 30 and conductive elements 40. Apparatus 10 may provide any electronic functionality that is or becomes known.

According to some embodiments, IC die 20 includes integrated electrical devices for providing microprocessor functionality and may be fabricated using any suitable materials and fabrication techniques. The electrical devices of IC die 20 may be electrically connected to conductive pillars 30 and/or conductive elements 40. The electrical devices may therefore also be connected to wires 50 via pillars 30 and elements 40. Wires 50 connected to conductive pillars 30 carry I/O signals and wires 50 connected to conductive elements 40 carry power or ground signals according to some embodiments.

In some embodiments, IC die 20 defines a plurality of inner apertures, and at least one of conductive elements 40 is disposed on two or more of the plurality of inner apertures and is electrically connected to an electrical conductor through the two or more inner apertures. IC die 20 may also define a plurality of peripheral apertures, with one of conductive pillars 30 being disposed on one of the plurality of peripheral apertures and electrically connected to a second electrical conductor through the peripheral aperture.

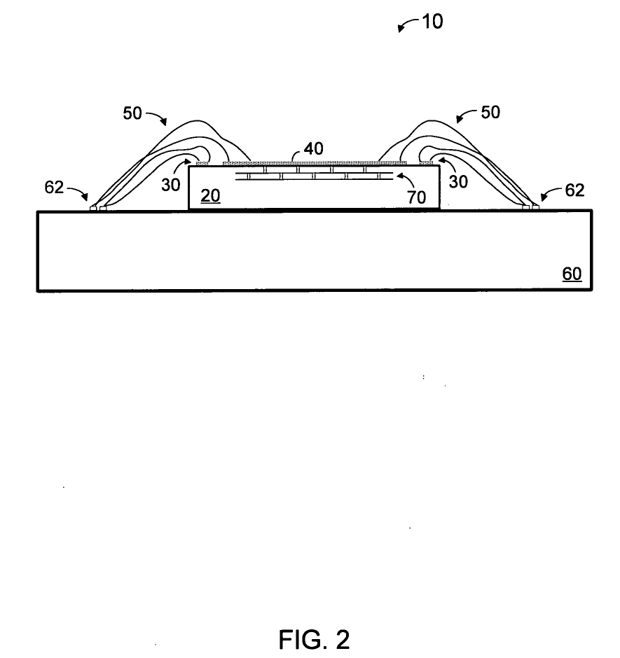

FIG. 2 is a cross-sectional view of apparatus 10 to further describe a. configuration thereof according to some embodiments. FIG. 2 shows IC die 20 coupled to IC package substrate 60. IC package substrate 60 may include a base dielectric layer with conductive fabricated thereon and layers separated by additional dielectric layers. The dielectric layers may be composed of any suitable material, including but not limited to bismaleimide triazine (BT) and FR4 in some embodiments. The conductive layers comprise reference planes for supplying reference voltages to electrical components that are connected to IC package substrate 60, or routing layers including conductive traces for carrying electrical signals between such electrical components. IC package substrate 60 includes contacts 62 to electrically connect wires 50 to the conductive layers.

FIG. 2 also illustrates power delivery grids. Power delivery grids 70 are intended to deliver power and ground signals to electrical devices of IC die 20. Power delivery grids 70 may be suitable for use in a flip-chip arrangement in addition to the illustrated wirebond arrangement. Grids 70 are composed of 1 μm thick copper according to some embodiments.

As shown, at least one of conductive elements 40 may be coupled to a central portion of grids 70. Conductive elements 40 may therefore provide delivery of power to a core of IC die 20 via a connected wire 50. Such an arrangement may exhibit a voltage drop that is smaller than a voltage drop exhibited by conventional arrangements in which power is delivered to the periphery of IC die 20 and grids 70. In this regard, conductive elements 40 may comprise copper having a thickness of 60 μm.

Two wires 50 are connected to each of illustrated pillars 30. These two wires are asymmetric according to some embodiments. Connecting two asymmetric wires to a pillar 30 may reduce a voltage drop between IC package substrate 60 and the pillar 30 in comparison to single-wire arrangements, and may also reduce crosstalk between the two wires.

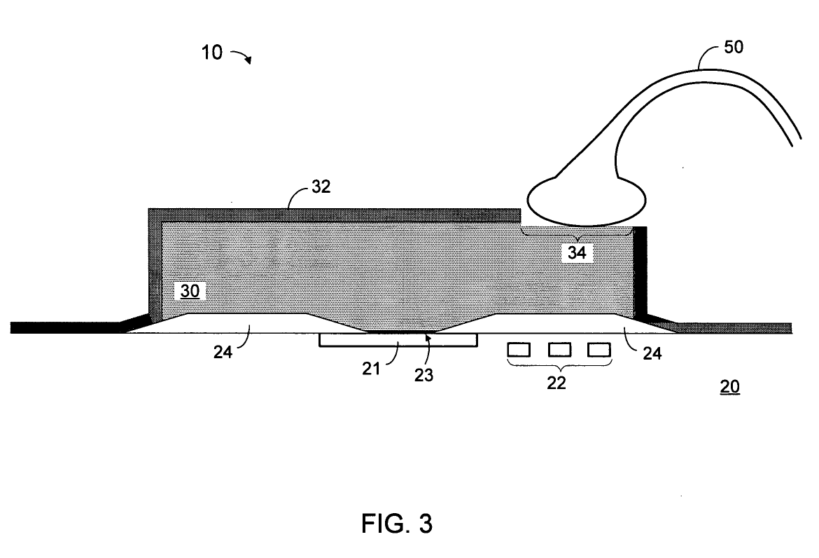

FIG. 3 is a close-up cross-sectional side view of apparatus 10 according to some embodiments. Conductive pillar 30 is partially covered by oxide-resistant layer 32, and wire 50 is bonded to bonding area 34 of pillar 30 that is not covered by layer 32. Conductive pillar 30 may comprise copper or any other conductive wire-bondable material, and oxide-resistant layer may comprise polyimide, silicon oxide, silicon nitride, and/or any other suitable material for preventing oxide growth on pillar 30. According to some embodiments, layer 32 comprises copper oxide or any other native oxide of the material of which pillar 30 is composed. As will be described below, layer 32 may retard growth of oxides on bonding area 34 of pillar 30 prior to bonding of wire 50 thereon. In some embodiments, conductive pillar 30 is ˜50 μm in height and layer 32 is ˜50 nm thick.

IC die 20 includes conductor 21 and conductive traces 22. IC die 20 may also include vias, electrical devices, and conductive planes. Conductor 21 is disposed below peripheral aperture 23. As shown in FIG. 1, peripheral aperture 23 and conductive pillar 30 are located on a periphery of IC die 20. Peripheral aperture 23 is defined by IC die 20 and is surrounded by passivation 24. Passivation 24 may comprise an electrical insulator (e.g., silicon nitride) and may also be compliant in some embodiments. According to some embodiments, passivation 24 is circular and defines an opening above aperture 23.

Conductive pillar 30 is electrically connected to conductor 21 through aperture 23. Accordingly, wire 50 is electrically connected to conductor 21. According to some embodiments, a conductive adhesion layer is deposited on conductor 23 prior to fabrication of pillar 30 thereon. The adhesion layer may comprise sputtered tin/copper.

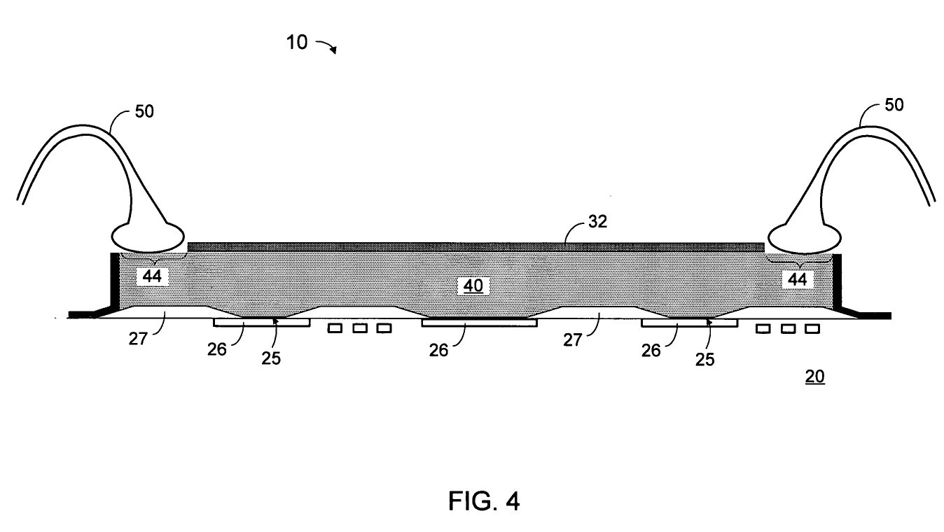

FIG. 4 illustrates a close-up cross-sectional side view of a conductive element 40 of apparatus 10 according to some embodiments. Conductive element 40 is disposed on two inner apertures 25 defined by IC die 20. Inner apertures 25 are disposed above conductors 26 and surrounded by insulating passivation 27. As shown in FIG. 1, inner apertures 25 may be defined within an interior area of a surface of IC die 20.

Conductive element 40 is partially covered by oxide-resistant layer 32, and wires 50 are bonded to areas 44 of element 40 that are not covered by layer 32. As described with respect to conductive pillar 30, element 40 may comprise copper or any other conductive wire-bondable material, and layer 32 may comprise any suitable oxide-resistant layer for retarding growth of oxides on bonding areas 44. Conductive element 40 is ˜50 μm in height and layer 32 is ˜50 nm thick according to some embodiments.

Conductors 26 are disposed below inner apertures 25 and are electrically connected to conductive element 40 through apertures 25. Conductors 26 may or may not be connected to one another within IC die 20. In some embodiments, conductors 26 carry power or ground signals between wires 50 and power delivery grid 70. In this regard, one or all of conductors 26 may be connected to a core portion of grid 70. Such an arrangement may reduce a voltage drop between wires 50 and a core of IC 20 in comparison to conventional systems.

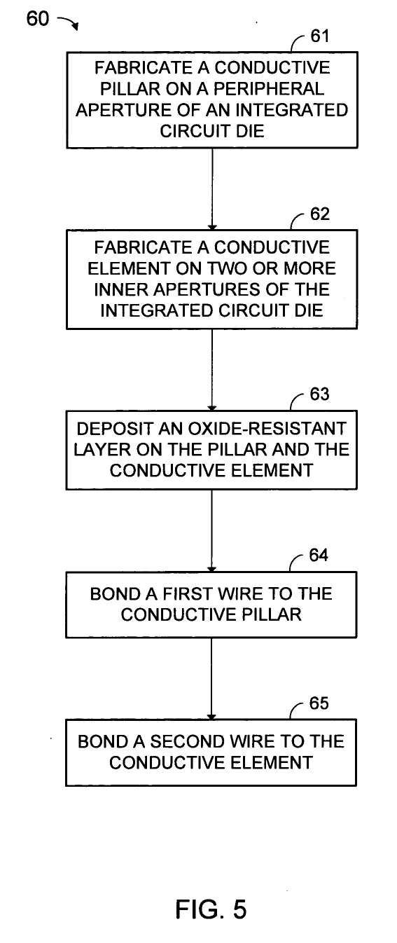

FIG. 5 is a diagram of process 60 to fabricate an apparatus according to some embodiments. Process 60 may be executed by one or more devices, and all or a part of process 60 may be executed manually. Process 60 may be executed by an entity different from an entity that assembles an IC package from an IC die and an IC package substrate.

Initially, at 61, a conductive pillar is fabricated on a peripheral aperture of an IC die. Next, a conductive element is fabricated on two or more inner apertures of the IC die at 62. As described with respect to FIGS. 3 and 4, the peripheral aperture may be disposed above a conductor to carry I/O signals within the IC die, and the inner apertures may be disposed above conductors to carry power or ground signals to a core of the IC die.

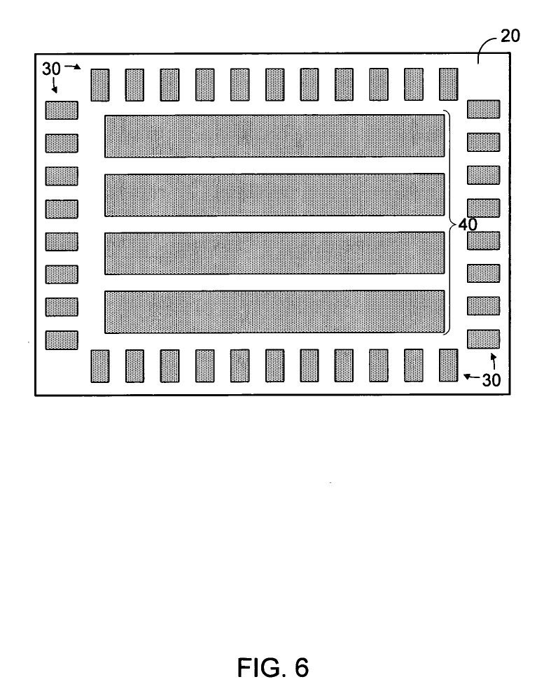

The conductive pillar and the conductive element may be fabricated using any suitable techniques that are or become known. According to some embodiments, the conductive pillar and the conductive element are fabricated simultaneously using a copper electrodeposition process. FIG. 6 is a top view of IC die 20 after some embodiments of 62. The illustrated pattern of conductive elements 40 and conductive pillars 30 may be achieved using photolithographic masking techniques.

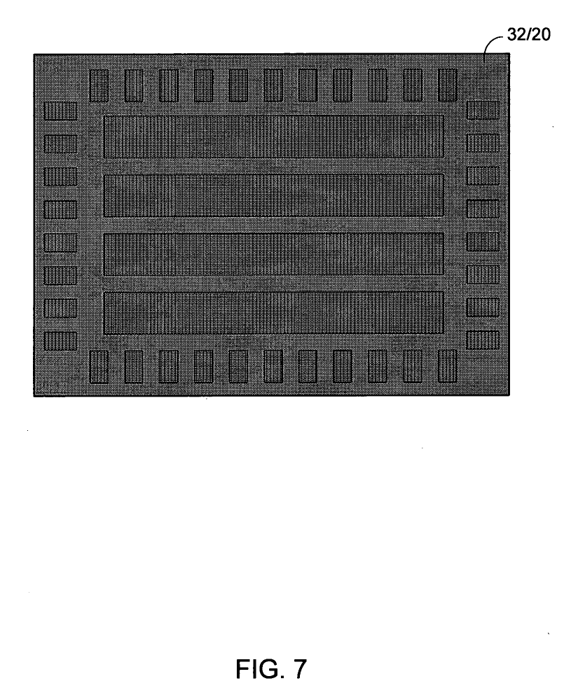

An oxide-resistant layer is deposited on the conductive pillar and the conductive element at 63. In some embodiments, the oxide-resistant layer is deposited using chemical vapor deposition and may comprise any suitable components. The layer may be deposited shortly after the elements and pillars are formed to retard the development of copper oxides thereon. The oxide-resistant layer may comprise a native oxide of the conductive pillar, in which case the layer may be “grown” at 63. FIG. 7 illustrates layer 32 disposed on IC die 20, pillars 30 and elements 40 according to some embodiments.

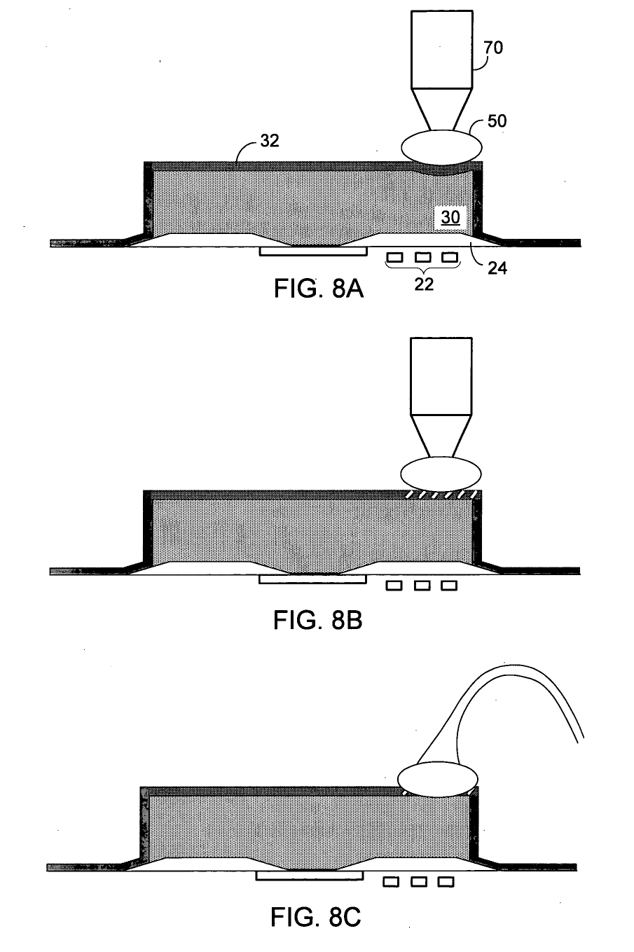

A first wire is bonded to the conductive pillar at 64. Bonding the first wire comprises establishing an electrical connection between the first wire and the conductive pillar. FIGS. 8A through 8C illustrate 64 according to some embodiments. FIG. 8A shows bonding head 70 pressing an end of wire 50 into oxide-resistant layer 32. As shown, layer and pillar 30 deform slightly in response to the pressure. Pillar 30 may be annealed after pillar 30 is fabricated to facilitate this deformation.

Bonding head 70 also or alternatively vibrates at or near a resonant frequency of layer 32 to allow wire 50 to penetrate and fragment layer 32 as shown in FIG. 8B. The resulting fragments may be dispersed uniformly at the interfacial bonding intermetallic (i.e., gold and copper) layer so as not to substantially affect the integrity or electrical resistance of the wirebond. FIG. 8C shows a resultant configuration.

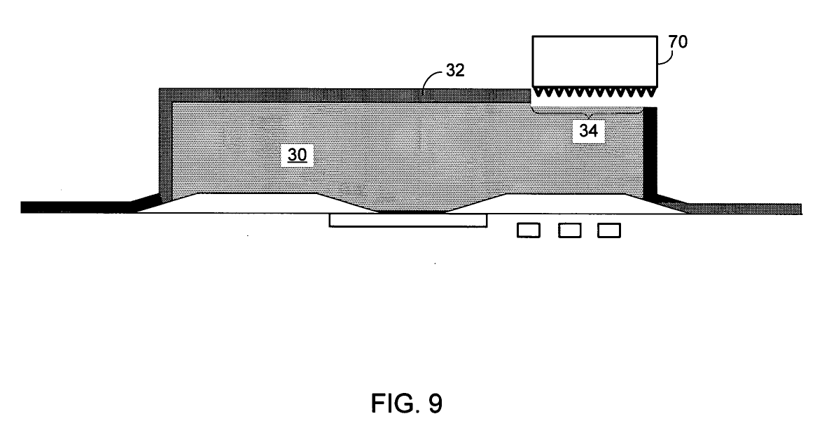

FIG. 9 illustrates another embodiment of 64. A portion of layer 32 is removed by mechanical micro-mill 80, which may comprise a high-speed diamond blade with Z-axis control. Micro-mill 80 may also remove a portion of pillar 30 as shown to substantially remove any oxides that may have formed thereon. The first wire may then be bonded to area 34 exposed by micro-mill 80.

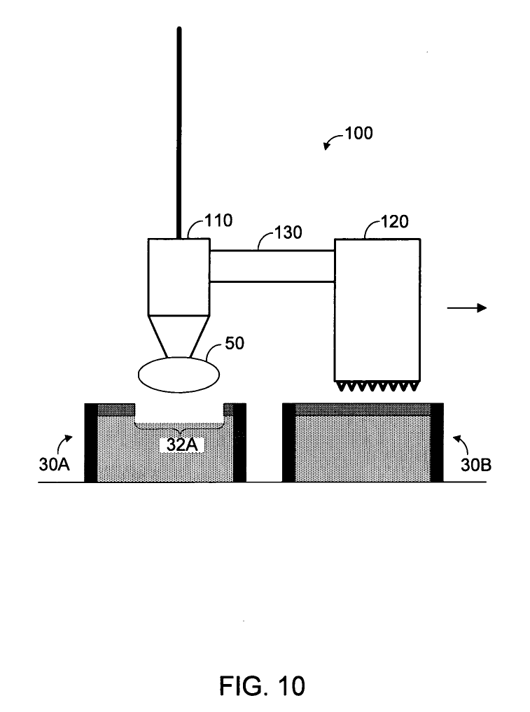

FIG. 10 illustrates yet another embodiment of 64. Device 100 comprises bonding head 110 and pre-clean tool 120 coupled to transducer block 130. Bonding head 110 and pre-clean tool 120 may each operate based on energy supplied by transducer block 130. Device 100 may simultaneously expose a bonding area of a conductive pillar and bond a first wire to an exposed area of an adjacent conductive pillar.

As shown, tool 120 has exposed bonding area 32A of pillar 30A. Device 100 then moves in the direction of the arrow to position head 110 over area 32A. Device 100 may subsequently move downward to bond wire 50 to area 32A and to expose a bonding area of pillar 30B.

Returning to process 60, a second wire is bonded to the conductive element at 65. The second wire may be bonded using any of the above-described techniques or any other suitable techniques. The second wire may be intended to carry power or ground signals to the conductive element. In some embodiments, more than one wire is bonded to a given conductive element as shown in FIG. 4.

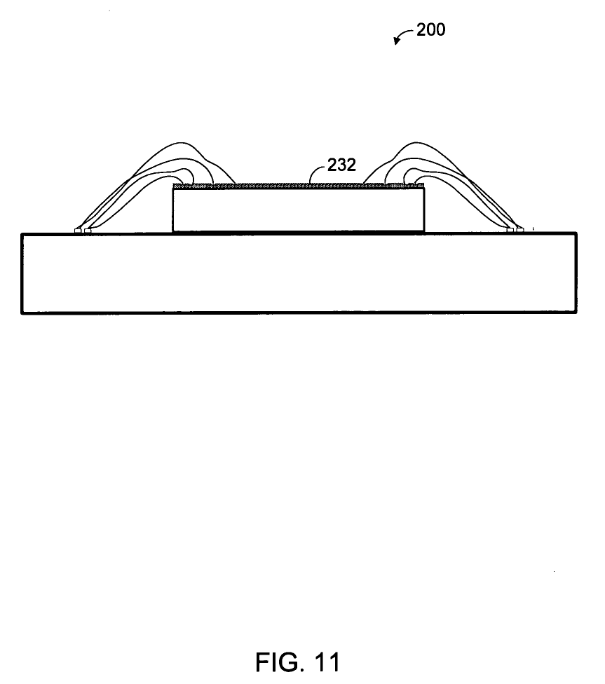

FIG. 11 is a side view of apparatus 200 fabricated according to some embodiments of process 60. Apparatus 200 is substantially identical to apparatus 10 but for oxide-resistant layer 232 fabricated thereon.

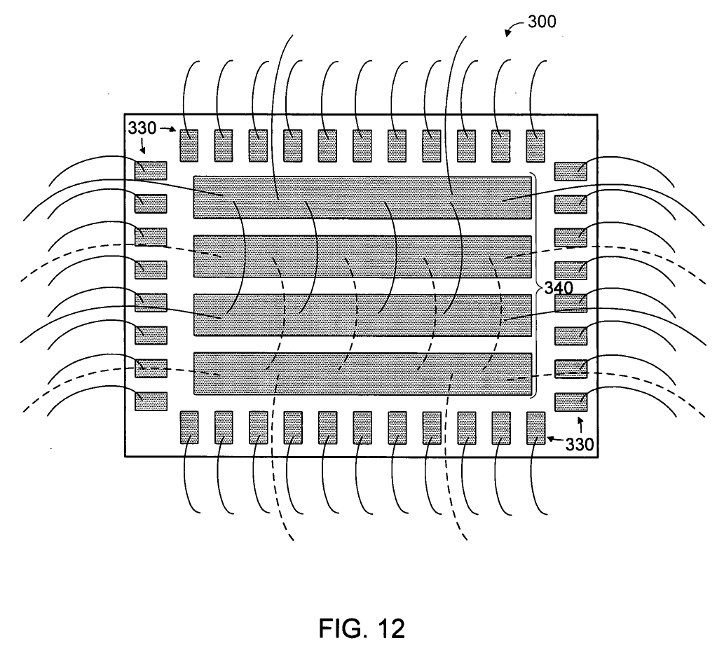

Many different layouts of conductive elements and/or copper pillars may be used in conjunction with some embodiments. Additionally or alternatively, embodiments may utilize many different wire bonding patterns. FIGS. 12 through 14 are top views of various apparatuses exhibiting various layouts and bonding patterns according to some embodiments. Each of FIGS. 12 through 14 omit an oxide-resistant layer for clarity, but it should be noted that each apparatus illustrated therein may include an oxide-resistant layer deposited thereon.

Wires bonded to peripheral pillars 330 of apparatus 300 are to carry I/O signals, while wires bonded to conductive elements 340 carry power and ground signals. In the illustrated embodiment, the dashed lines represent wires carrying ground signals and the solid lines connected to conductive elements 340 represent wires carrying power signals. As shown, some wires are merely used to directly connect two conductive elements 340. Such wires may reduce a voltage drop exhibited by apparatus 300.

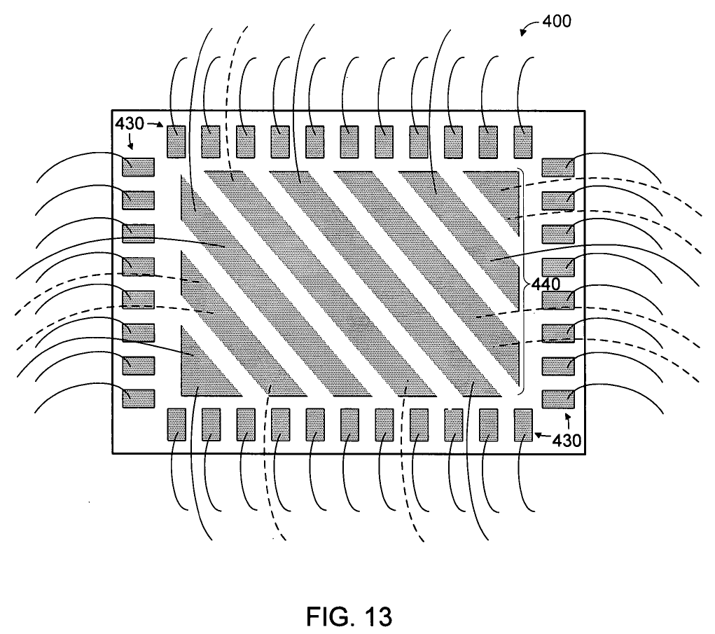

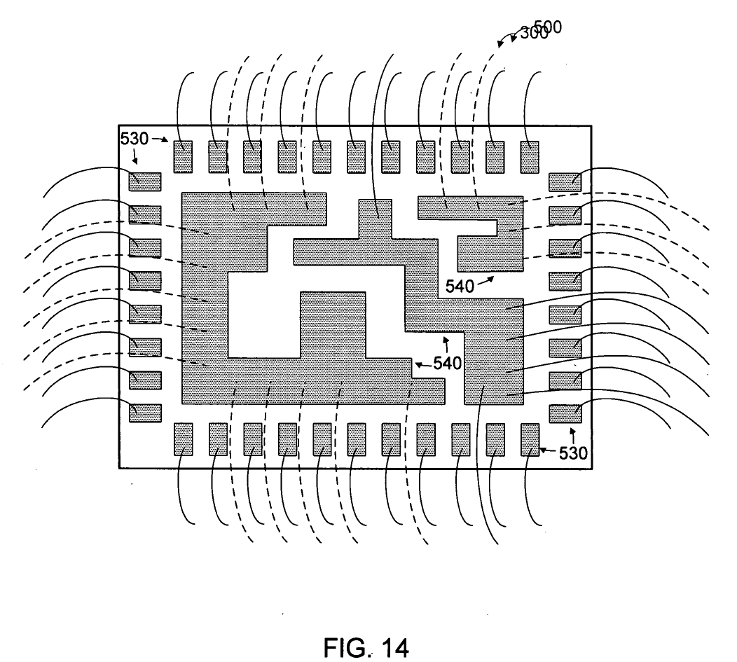

Apparatuses 400 and 500 of FIGS. 13 and 14 also includes wires bonded to peripheral pillars 430/530 to carry I/O signals, and wires bonded to conductive elements 440/540 carry power and ground signals. Again, the dashed lines represent wires carrying ground signals and the solid lines connected to conductive elements 440/540 represent wires carrying power signals. The layout of conductive elements 540 of apparatus 500 in particular may be used to reduce electromagnetic interference and/or to provide shielding.

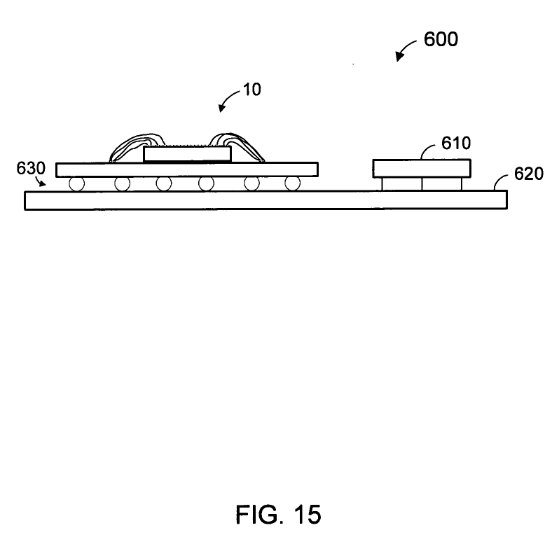

FIG. 15 is a cross-sectional side view of system 600 according to some embodiments. System 600 may comprise components of a server platform. System 600 includes apparatus 10 as described above, memory 610 and motherboard 620. Apparatus 10 may comprise a microprocessor.

Motherboard 620 may electrically couple memory 610 to apparatus 10. More particularly, motherboard 620 may comprise a memory bus (not shown) that is electrically coupled to solder balls 630 of apparatus 10 and to memory 610. Memory 610 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

What is claimed is:

1. An apparatus comprising:
an integrated circuit die defining a plurality of inner apertures; and
a conductive element disposed on two or more of the plurality of inner apertures and electrically connected to an electrical conductor through the two or more inner apertures.

2. An apparatus according to claim 1, wherein the integrated circuit die defines a plurality of peripheral apertures, and further comprising:
a conductive pillar disposed on one of the plurality of peripheral apertures and electrically connected to a second electrical conductor through the peripheral aperture.

3. An apparatus according to claim 2, further comprising:
a first wire bonded to the conductive pillar;
a second wire bonded to the conductive element; and
an integrated circuit package coupled to the integrated circuit die, the integrated circuit package comprising:
a first contact bonded to the first wire; and
a second contact bonded to the second wire.

4. An apparatus according to claim 3, further comprising:
a third wire bonded to the conductive element and to the second contact,
wherein the second wire and the third wire are asymmetric.

5. An apparatus according to claim 3, further comprising:
an oxide-resistant layer on at least a portion of the conductive element and on at least a portion of the conductive pillar.

6. An apparatus according to claim 1, further comprising:
an oxide-resistant layer on at least a portion of the conductive element.

7. An apparatus according to claim 1, wherein the electrical conductor is to carry a power signal.

8. An apparatus according to claim 7, further comprising:
a second conductive element disposed on a second two or more of the plurality of inner apertures and electrically connected to a second electrical conductor through the second two or more inner apertures,
wherein the second electrical conductor is to carry a ground signal.

9. An apparatus according to claim 7, further comprising:
a second conductive element disposed on a second two or more of the plurality of inner apertures and electrically connected to a second electrical conductor through the second two or more inner apertures,
wherein the second electrical conductor is to carry a power signal.

10. An apparatus according to claim 1, further comprising:
a power delivery grid within the integrated circuit die,
wherein the electrical conductor is electrically connected to a core portion of the power delivery grid.

11. A method comprising:
fabricating a conductive element on two or more inner apertures of an integrated circuit die,
wherein the conductive element is electrically connected to an electrical conductor through the two or more inner apertures.

12. A method according to claim 11, further comprising:
fabricating a conductive pillar on one of a plurality of peripheral apertures of the integrated circuit die,
wherein the conductive pillar is electrically connected to a second electrical conductor through the peripheral aperture.

13. A method according to claim 12, further comprising:
bonding a first wire to the conductive pillar;
bonding a second wire to the conductive element; and
bonding the first wire to a first contact of an integrated circuit package; and
bonding the second wire to a second contact of the integrated circuit package.

14. A method according to claim 13, further comprising:
bonding a third wire to the conductive element and to the second contact,
wherein the second wire and the third wire are asymmetric.

15. A method according to claim 12, further comprising:
depositing an oxide-resistant layer on at least a portion of the conductive element and on at least a portion of the conductive pillar.

16. A method according to claim 11, further comprising:
depositing an oxide-resistant layer on at least a portion of the conductive element.

17. A method according to claim 11, wherein the electrical conductor is to carry a power signal.

18. A method according to claim 17, further comprising:
fabricating a second conductive element disposed on a second two or more of the plurality of inner apertures and electrically connected to a second electrical conductor through the second two or more inner apertures,
wherein the second electrical conductor is to carry a ground signal.

19. A method according to claim 17, further comprising:
fabricating a second conductive element disposed on a second two or more of the plurality of inner apertures and electrically connected to a second electrical conductor through the second two or more inner apertures,
wherein the second electrical conductor is to carry a power signal.

20. A method according to claim 11, wherein the electrical conductor is electrically connected to a core portion of a power delivery grid within the integrated circuit die.

21. A system comprising:
a microprocessor comprising:
an integrated circuit die defining a plurality of inner apertures; and
a conductive element disposed on two or more of the plurality of inner apertures and electrically connected to an electrical conductor through the two or more inner apertures; and
a double data rate memory electrically coupled to the microprocessor.

22. A system according to claim 21, wherein the integrated circuit die defines a plurality of peripheral apertures and further comprises:
a conductive pillar disposed on one of the plurality of peripheral apertures and electrically connected to a second electrical conductor through the peripheral aperture.

23. A system according to claim 22, the microprocessor further comprising:
a first wire bonded to the conductive pillar;
a second wire bonded to the conductive element; and
an integrated circuit package coupled to the integrated circuit die, the integrated circuit package comprising:
a first contact bonded to the first wire; and
a second contact bonded to the second wire.

24. A system according to claim 23, the microprocessor further comprising:
a third wire bonded to the conductive element and to the second contact,
wherein the second wire and the third wire are asymmetric.

25. A system according to claim 22, the microprocessor further comprising:
an oxide-resistant layer on at least a portion of the conductive element and on at least a portion of the conductive pillar.

26. A system according to claim 21, the microprocessor further comprising:
a second conductive element disposed on a second two or more of the plurality of inner apertures and electrically connected to a second electrical conductor through the second two or more inner apertures,
wherein the electrical conductor and the second electrical conductor are to carry a power signal.

27. A system according to claim 21, the microprocessor further comprising:
a power delivery grid within the integrated circuit die,
wherein the electrical conductor is electrically connected to a core portion of the power delivery grid.
